(19) United States
(12) Patent Application Publication
(10) Pub. No.: US 2013/0075804 A1
(43) Pub. Date: Mar. 28, 2013

(54) HIGH DENSITY SEMICONDUCTOR MEMORY DEVICE AND METHOD FOR MANUFACTURING THE SAME

(71) Applicant: Electronics and Telecommunications Research Institute, Daejeon (KR)

(72) Inventors: Taeyoub KIM, Seoul (KR); Myungsim JUN, Daejon (KR); Yark-Yeon KIM, Daejon (KR); Moon-Gyu JANG, Daejon (KR); Chel-Jong CHOI, Daejon (KR); Seong-Jae LEE, Daejon (KR); Byoungchul PARK, Daejon (KR)

(73) Assignee: Electronics and Telecommunications Research Institute, Daejeon (KR)

(21) Appl. No.: 13/683,837

(22) Filed: Nov. 21, 2012

Related U.S. Application Data
(62) Division of application No. 11/950,291, filed on Dec. 4, 2007.

(30) Foreign Application Priority Data
Dec. 4, 2006 (KR) 10-2006-0121224
Sep. 18, 2007 (KR) 10-2007-0094687

(51) Int. Cl. H01L 29/788; H01L 29/66

(52) U.S. Cl. CPC H01L 29/788; H01L 29/66825
USPC 257/315; 438/264

(57) ABSTRACT

Provided are a high density semiconductor memory device capable of precisely reading data by suppressing the occurrence of a leakage current due to the high-integration of the semiconductor memory device, and a method for manufacturing the semiconductor memory device. The high density semiconductor memory device includes: source and drain electrodes disposed over a substrate, and forming a Schottky junction with a channel region; and a floating gate disposed over the substrate of the channel region, and configured with a plurality of nanodots. The nanodots may be formed of a silicon compound or any material that can be charged.

### CROSS-REFERENCE(S) TO RELATED APPLICATIONS

The present invention claims priority of Korean Patent Application Nos. 10-2006-0121224 and 10-2007-0094687, filed on Dec. 4, 2006, and Sep. 18, 2007, respectively, which are incorporated herein by reference.

### BACKGROUND OF THE INVENTION

1. Field of the Invention

The present invention relates to a semiconductor memory device and a method for manufacturing the same; and, more particularly, to a high density semiconductor memory device capable of precisely reading data by suppressing the occurrence of a leakage current due to the high-integration of the semiconductor memory device, and a method for manufacturing the semiconductor memory device.

This work was supported by the IT R&D program of MIC/IITA.

2. Description of Related Art

Demands for flash memories among a variety of semiconductor memory devices have explosively increased for past several years with the advent of mobile devices such as mobile phones, cameras and MP3s. As information technology and household electronic technology are developing rapidly, much interest is being paid on flash memories as storage media for information apparatus and household electronic appliances.

FIG. 1 is a cross-sectional view of a conventional flash memory. Referring to FIG. 1, the conventional flash memory includes a substrate 100, a tunneling dielectric layer 120, a floating gate 130, a gate dielectric layer 140 and a control gate 150. In the substrate 100, a channel region 160 and source and drain regions 110 are provided. The source and drain regions 110 are in contact with the channel region 160 and provided at both sides of the channel region 160. The tunneling dielectric layer 120 is disposed on the substrate 100 of the channel region 160.

The floating gate 130 is formed of polysilicon on the tunneling dielectric layer 120. The gate dielectric layer 140 is disposed on the floating gate 130 and the control gate 150 is disposed on the gate dielectric layer 150. The flash memory having the above configuration performs programming/erasing operations in such a way that a transistor changes its threshold voltage by injecting or removing charges into/from the floating gate 130.

However, a space between the source and drain regions 110 of the flash memory device recently decreases as the design rule of semiconductor devices gets smaller, whereas doping concentrations of the source and drain regions 110 and the channel region 160 increase, leading to short channel effect (SCE). In particular, it is difficult to precisely read data because a threshold voltage of a transistor changes due to a leakage current caused by the SCE.

In addition, the conventional flash memory device uses trap sites provided in the floating gate 130 so as to store charges. Therefore, in order to secure a sufficient space, i.e., a number of trap sites, for storing data, the floating gate 130 must have a great thickness, which makes it difficult to realize a high density flash memory. In addition, since a trap force is weak when trapping charges into trap sites, there is a problem in that a data-storing time, i.e., a retention time is reduced.

Furthermore, in the conventional flash memory device, charges are injected or removed into/from the floating gate 130 using hot electron injection or Fowler-Nordheim (F-N) tunneling requiring a high voltage, for example, a voltage in the range of approximately 14 V to approximately 20 V, resulting in high power consumption. Accordingly, the conventional flash memory device is disadvantageous in that the tunneling dielectric layer 120 is deteriorated due to a stress applied thereto while injecting or removing charges into/from the floating gate 130 and further data stored in the floating gate 130 may be lost due to charge leakage.

### SUMMARY OF THE INVENTION

An embodiment of the present invention is directed to providing a high density semiconductor device capable of precisely reading data by suppressing the occurrence of a leakage current due to the high-integration of the semiconductor memory device, and a method for manufacturing the high density semiconductor memory device.

Another embodiment of the present invention is directed to providing a high density semiconductor device capable of simplifying a manufacturing process of the high density semiconductor device, and a method for manufacturing the high density semiconductor memory device.

In accordance with an aspect of the present invention, there is provided a high density semiconductor memory device, which includes: source and drain electrodes disposed over a substrate, and forming a Schottky junction with a channel region; and a floating gate disposed over the substrate of the channel region, and configured with a plurality of nanodots. The high density semiconductor memory device further includes a gate dielectric layer formed over the floating gate. The high density semiconductor memory device further includes: a tunneling dielectric layer disposed between the substrate of the channel region and the floating gate; and a control gate disposed over the floating gate.

Herein, the channel region may include silicon and the source and drain electrodes may include metal silicide. The source and drain electrodes may include a material selected from the group consisting of erbium (Er), ytterbium (Yb), samarium (Sm), yttrium (Y), gadolinium (Gd), terbium (Tb) and cerium (Ce) when an electron is used as a majority carrier. Herein, the source and drain electrodes may include a material selected from the group consisting of platinum (Pt), lead (Pb) and iridium (Ir) when a hole is used as a majority carrier.

Herein, the nanodots may be formed using a silicon compound as a basal body. The silicon compound basal body may include one selected from the group consisting of silicon oxide, silicon nitride and silicon carbon. The high nanodots may also be formed using a chargeable material as a basal body.

The substrate may include one of a bulk silicon substrate and a silicon-on-insulator (SOI) substrate.

In accordance with another aspect of the present invention, there is provided a method for manufacturing a high density semiconductor memory device, the method including the steps of: a) forming a channel region and source and drain electrodes in a substrate, the source and drain electrodes forming a Schottky junction with the channel region; b) forming a tunneling dielectric layer over the substrate; c) forming a floating gate over the tunneling dielectric layer, the floating gate comprising a plurality of nanodots; d) forming a control gate over the floating gate; and e) etching the control gate, the floating gate and the tunneling dielectric layer to expose the source and drain electrodes. The method further includes the step of: f) forming a gate dielectric layer over the floating gate.

The channel region may be formed of silicon, and the source and drain electrodes may be formed of metal silicide. Herein, the source and drain electrodes may be formed of a material selected from the group consisting of erbium (Er), ytterbium (Yb), samarium (Sm), yttrium (Y), gadolinium (Gd), terbium (Tb) and cerium (Ce) when an electron is used as a majority carrier. Herein, the source and drain electrodes may be formed of a material selected from the group consisting of platinum (Pt), lead (Pb) and iridium (Ir) when a hole is used as a majority carrier.

The nanodots may be formed using a silicon compound as a basal body. The silicon compound basal body may include one selected from the group consisting of silicon oxide, silicon nitride and silicon carbon. The nanodots may be formed using a chargeable material as a basal body.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

### BRIEF DESCRIPTION OF THE DRAWINGS

FIG. 1 is a cross-sectional view of a conventional flash memory.

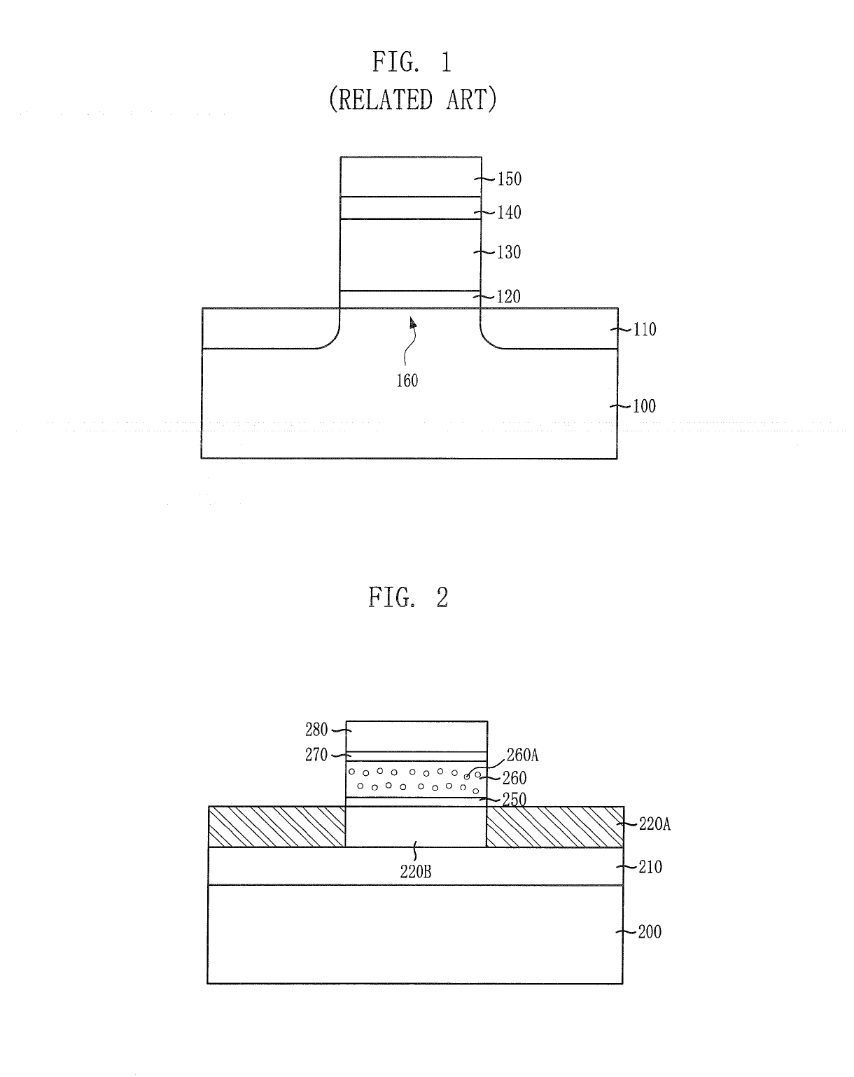

FIG. 2 is a cross-sectional view of a high density semiconductor memory device in accordance with an embodiment of the present invention.

FIGS. 3A to 3D are cross-sectional views illustrating a method for manufacturing a high density semiconductor memory device in accordance with an embodiment of the present invention.

FIG. 4 is a scanning electron microscope (SEM) micrograph illustrating silicon nanodots and silicon nitride basal body prepared in accordance with an embodiment of the present invention.

### DESCRIPTION OF SPECIFIC EMBODIMENTS

The advantages, features and aspects of the invention will become apparent from the following description of the embodiments with reference to the accompanying drawings, which is set forth hereinafter.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Like reference numerals refer to like elements throughout the drawings.

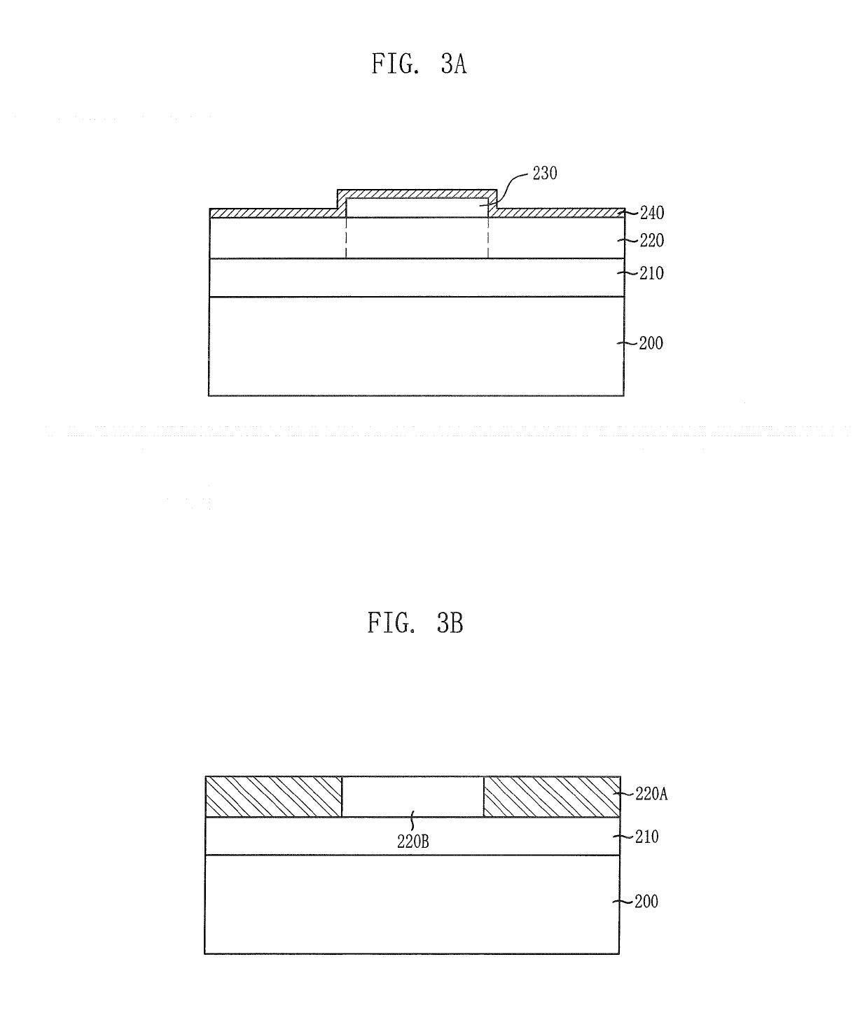

FIG. 2 is a cross-sectional view of a high density semiconductor memory device in accordance with an embodiment of the present invention.

Referring to FIG. 2, the high density semiconductor memory device of the present invention includes source and drain electrodes 220A and a floating gate 260A. The source and drain electrodes 220A are provided in a substrate and forms a Schottky junction with a channel region 220B. The floating gate 260A is disposed over the substrate, and configured with a plurality of nanodots. The semiconductor memory device may further include a tunneling dielectric layer 250 between the floating gate 260A and the substrate of the channel region 220B, and a control gate 280 disposed over the floating gate 260A. The semiconductor memory device may further include a gate dielectric layer 270 on the floating gate 260A.

The channel region 220B may be formed of silicon, and the source and drain electrodes 220A may be formed of metal silicide. The Schottky junction can be provided between the channel region 220B and the source and drain electrodes 220A. Accordingly, a Schottky barrier can be formed between the channel region 220B and the source and drain electrodes 220A, thus suppressing the occurrence of a leakage current between the source and drain electrodes 220A.

If an electron is used as a majority carrier, the source and drain electrodes 220A may be formed of a material having a low Schottky barrier with respect to the electron, for example, a material selected from the group consisting of erbium (Er), ytterbium (Yb), samarium (Sm), yttrium (Y), gadolinium (Gd), terbium (Tb) and cerium (Ce). On the contrary, if a hole is used as a majority carrier, the source and drain electrodes 220A may be formed of a material having a low Schottky barrier with respect to the hole, for example, a material selected from the group consisting of platinum (Pt), lead (Pb) and iridium (Ir).

The floating gate 260A configured with the nanodots may be formed using a silicon compound as a basal body 260. The silicon compound basal body 260 may be formed of one material selected from the group consisting of silicon oxide, silicon nitride and silicon carbon. The nanodots may be also formed of any material as long as the material is chargeable. The floating gate 260A stores data by injecting or removing charges into/from the silicon nanodots.

Herein, the silicon compound basal body 260 may serve as a gate dielectric layer because it is formed of an insulation material such as silicon oxide, silicon nitride or silicon carbon.

If the control gate 280 is not sufficiently insulated from an underlying structure thereof only using the silicon compound basal body 260, the gate dielectric layer 270 may be further provided between the control gate 280 and the silicon compound basal body 260.

The substrate may include a bulk silicon substrate. It is preferable that a silicon-on-insulator (SOI) substrate is used as the substrate so as to reduce a leakage current of a high density semiconductor memory device and to increase a driving current. The SOI substrate may include a support substrate 200 for mechanical support, a buried oxide layer 210 disposed on the support substrate 200 and a silicon substrate (a region where the channel region 220B and the source and drain electrodes 220A are provided) disposed on the buried oxide layer 210.

Preferably, the silicon substrate has a predetermined thickness that is sufficient for allowing an electric field controlled by the control gate 280 to fully control the channel region 220B. Therefore, a thickness of the channel region 220B, which is under control of the control gate 280, is reduced so that it is possible to more easily control the formation of an inversion layer. Resultingly, this leads to a decrease in a leakage current between the source and drain electrodes 220A.

As such, the leakage current due to the high-integration of the semiconductor memory device can be suppressed between the source and drain electrodes 220A, and between the floating gate 260A and the source and drain electrodes 220A, by forming the source and drain electrodes 220A of metal silicide. Therefore, a change in a threshold voltage of a semiconductor memory device can be prevented, thus making it possible to precisely read data. Also, it is possible to suppress the occurrence of a leakage current between the floating gate 260A and the source and drain electrodes 220A because the Schottky barrier also exists between the floating gate 260A and the source and drain electrodes 220A.

Also, because the floating gate 260A is configured with the plurality of silicon nanodots in the present invention, a sufficient space for storing charges can be secured even if the floating gate 260A has a volume smaller than the conventional floating gate. Accordingly, the floating gate 260A is significantly reduced in size, improving integration degree of a semiconductor memory device.

Furthermore, in accordance with the present invention, even if there is a short between the floating gate and the source and drain electrodes 220A due to the deterioration of the tunneling dielectric layer 250, only minority of shorted silicon nanodots are affected but other majority of silicon nanodots are not affected, making it possible to secure stable operating characteristics of a device. That is, it is possible to maintain uniform distribution of a threshold voltage.

In the present invention, moreover, since charges are trapped in potential wells of the silicon nanodots having high potential barrier, it is possible to prevent the occurrence of a leakage current and increase the retention time.

In addition, because the leakage current can be effectively suppressed by forming the source and drain electrode 220A of metal silicide and configuring the floating gate 260A with the plurality of silicon nanodots, the tunneling dielectric layer 250 can have a thickness smaller than that of the conventional semiconductor memory device, for example, a thickness of approximately 6 nm or smaller, thus allowing charges to directly tunnel through the tunneling dielectric layer 250 when injecting or removing the charges into/from the floating gate 260A.

The application of the direct tunneling mechanism can improve the durability of the tunneling dielectric layer 250, improve an operating speed of a semiconductor memory device, and also reduce an operating voltage. This is attributed to that the direct tunneling is a process requiring a lower voltage than typical hot electron injection or F-N tunneling, for example, a voltage in the range of approximately 3 V to approximately 5 V.

Hereinafter, a method for manufacturing a high density semiconductor memory device in accordance with the present invention will be described in detail with reference to the accompanying drawings. In below description, well-known technologies of a manufacturing method of a semiconductor device or a related layer-forming method will not be illustrated, which means that the spirit and scope of the present invention are not limited by the well-known technologies.

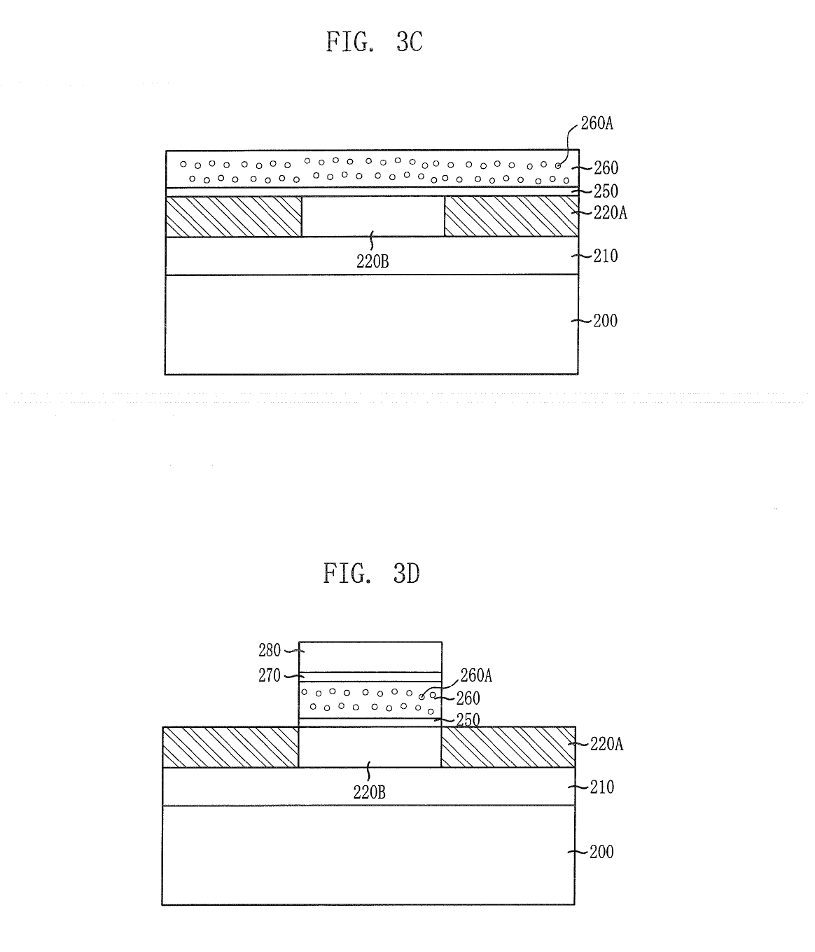

FIGS. 3A to 3D are cross-sectional views illustrating a method for manufacturing a high density semiconductor memory device in accordance with an embodiment of the present invention.

Referring to FIG. 3A, an SOI substrate is prepared, which includes a support substrate 200 for mechanical support, a buried oxide layer 210 disposed on the support substrate 200 and a silicon substrate 220 disposed on the buried oxide layer 210. Instead of the SOI substrate, a bulk silicon substrate may be used as the substrate.

Herein, it is preferable that the silicon substrate 220 is formed to a predetermined thickness that is sufficient for allowing an electric field controlled by a control gate 280, which will be formed during a subsequent process, to fully control the channel region 220B. Therefore, a thickness of a channel region, which is under control of the control gate, is reduced so that it is possible to more easily control the formation of an inversion layer. Resultingly, a leakage current between the source and drain electrodes 220A can be reduced.

After forming a sacrificial layer on the silicon substrate 220, the sacrificial layer is selectively etched to form a sacrificial pattern 230 that opens a region where source and drain electrodes will be formed. The silicon substrate 220 covered with the sacrificial pattern 230 becomes a channel region through a subsequent process (see FIG. 3B).

A metal layer 240 is formed on an entire surface of the semiconductor substrate 220 including the sacrificial pattern 230. The metal layer 240 is used for forming source and drain electrodes of metal silicide. If an electron is used as a majority carrier, the metal layer 220 may be formed of a material having a low Schottky barrier with respect to the electron, for example, a material selected from the group consisting of Er, Yb, Sm, Y, Gd, Tb and Ce.

On the contrary, if a hole is used as a majority carrier, the metal layer 220 may be formed of a material having a low Schottky barrier with respect to the hole, for example, a material selected from the group consisting of Pt, Pb and Ir.

Referring to FIG. 3B, a heat treatment is performed to form source and drain electrodes 220A of metal silicide. Specifically, the heat treatment is a process of reacting the metal layer 220 and the silicon substrate with each other to form the metal silicide. The heat treatment may be performed using one process selected from the group consisting of a rapid thermal annealing (RTA) process, a furnace annealing process and a laser annealing process. For example, the metal layer 240 is formed of erbium (Er), and thereafter heat-treated using the RTA process at a temperature ranging from approximately 500C.° to approximately 600C.°, thereby forming the source and drain electrodes 22A of erbium silicide.

Herein, it is preferable to perform the heat treatment for a duration that is sufficient for allowing bases (bottoms) of the source and drain electrodes 220A to contact the top of the buried oxide layer 210.

Thereafter, an unreacted metal layer is removed, which does not react with silicon during the heat treatment. The unreacted metal layer may be removed using a wet etch process or a dry etch process. In the case of using the wet etch process, the unreacted metal layer may be removed using aqua regia with hydrochloric (HCl) acid and nitric (HNO₃) acid mixed or sulfuric peroxide mixture (SPM) with sulfuric (H₂SO₄) acid or hydrogen peroxide (H₂O₂) mixed. In the case of using the dry etch process, the unreacted metal layer may be removed using an argon gas sputtering method.

Afterwards, the sacrificial pattern 230 is removed. Through the above-described processes, it is possible to form the channel region 220B and the source and drain electrodes 220A forming a Schottky junction with the channel region 220B.

Referring to FIG. 3C, a tunneling dielectric layer 250 is formed on the semiconductor substrate provided with the channel region 220B and the source and drain electrodes 220A. The tunneling dielectric layer 250 may be formed using various publicly known layer-forming techniques. For example, the tunneling dielectric layer 250 may be formed of silicon oxide to form an insulation layer with excellent properties through a thermal oxidation process.

The semiconductor memory device of the present invention can suppress the occurrence of a leakage current by forming the source and drain electrodes 220A of metal silicide and a floating gate of a plurality of nanodots, thus reducing the thickness of the tunneling dielectric layer 250. The nanodots may be formed of silicon or any material that is chargeable.

A floating gate 260A configured with a plurality of silicon nanodots is formed on the tunneling dielectric layer 250. The floating gate 260A may be formed using a silicon compound as a basal body. The silicon compound basal body 260 may be formed of one material selected from the group consisting of silicon oxide, silicon nitride and silicon carbon.

A method of forming the floating gate 260A configured with the plurality of silicon nanodots using the silicon compound as the basal body 260 will be more fully described below. Here, the silicon compound basal body 260 is formed of, for example, silicon nitride.

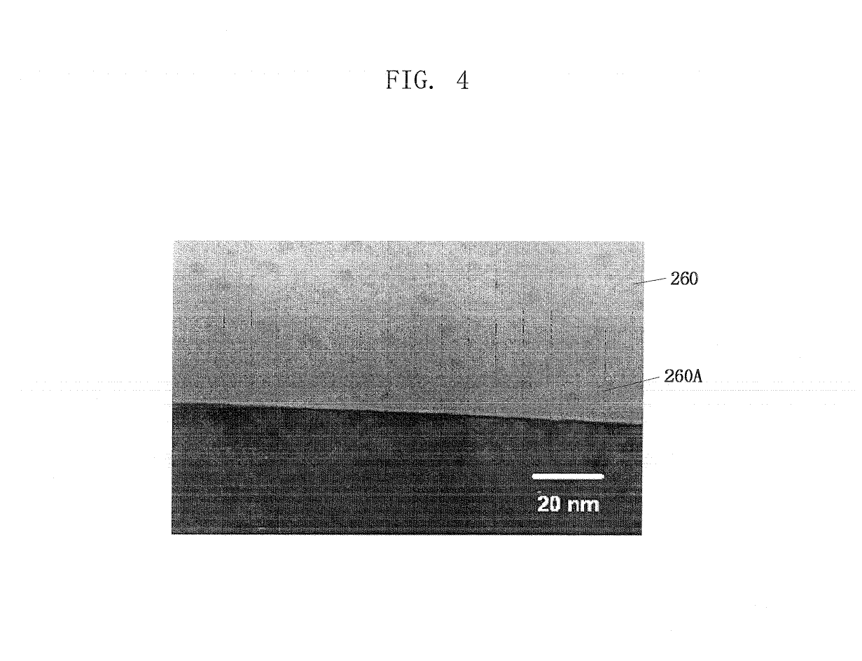

The plurality of silicon nanodots dispersed into the silicon nitride basal body can be grown through plasma enhanced chemical vapor deposition (PECVD) using an argon gas, a silicon source gas, a silicon source gas such as a silane gas, and a nitrogen-containing gas such as a gas mixture of nitrogen (N₂) gas and ammonia (NH₃) gas (see FIG. 4). In order to form the silicon nanodots with good nanocrystal structure in the silicon nitride, it is preferable to control a growth rate in the range of approximately 1.3 nm/min to approximately 1.8 nm/min.

To this end, the deposition process is performed under the condition that plasma power is set to approximately 5 W while a mixture gas in which the silicon source gas is diluted to a percent ratio of approximately 1% to approximately 50% with an argon gas is being supplied into a reaction chamber at a flow rate ranging from approximately 1 sccm to approximately sccm, and the nitrogen-containing gas is being supplied into the reaction chamber at a flow rate of approximately 500 sccm or more. Accordingly, a concentration of a radical generated by plasma can be reduced to thereby slowly grow the silicon nitride.

The silicon nanodots formed by the above-described method has superior nanocrystal structure to silicon nanodots formed by a chemical vapor deposition (CVD) method, and thus it is not necessary to perform a post treatment such as a thermal treatment (see FIG. 4).

Referring to FIG. 3D, a gate dielectric layer 270 is formed on the floating gate 260A. The gate dielectric layer 270 may be formed of silicon oxide using a low pressure CVD (LPCVD) process.

The silicon compound basal body 260 may serve as a gate dielectric layer because it is formed of an insulation material such as silicon oxide, silicon nitride or silicon carbon. If a control gate 280, which will be formed in a subsequent process, is sufficiently insulated from an underlying structure thereof only using the silicon compound basal body 260, a forming process of the gate dielectric layer 270 may be omitted.

Thereafter, the control gate 280 is formed on the gate dielectric layer 270. The control gate may be formed of one selected from the group consisting of polysilicon, metal such as tungsten (W) and titanium (Ti), conductive metal nitride such as titanium nitride, and a metal silicide such as tungsten silicide and titanium silicide.

Subsequently, a hard mask pattern (not shown) is formed on the control gate 280, and thereafter the control gate 280, the gate dielectric layer 270, the silicon compound basal body 260 and the tunneling dielectric layer 250 are etched using the hard mask pattern as an etch barrier, thereby exposing a region of the silicon substrate where the source and drain electrodes 220A are formed.

Through the above-described processes, it is possible to form the high density semiconductor memory device including the source and drain electrodes 220A formed of metal silicide and the floating gate 260A formed of the plurality of silicon nanodots.

In this way, the silicon compound basal body 260 for forming the floating gate 260A having the plurality of silicon nanodots serves as the gate dielectric layer, thus reducing number of process steps and manufacturing cost of a semiconductor memory device as well.

In the semiconductor memory device of the present invention, the leakage current due to the high-integration of the semiconductor memory device can be suppressed between the source and drain electrodes 220A, and between the floating gate 260A and the source and drain electrodes 220A, by forming the source and drain electrodes 220A of metal silicide. Therefore, a change in a threshold voltage of a semiconductor memory device can be prevented, thus making it possible to precisely read data.

Furthermore, it is possible to suppress the occurrence of a leakage current of the floating gate 260A caused by the deterioration of the tunneling dielectric layer 250 through forming the floating gate 260A as a plurality of silicon nanodots, thereby significantly reducing a size of the floating gate 260A to improve integration degree. Also, a retention time can be increased by virtue of a strong trap force of the silicon nanodot.

Moreover, a thickness of the tunneling dielectric layer 250 can be reduced by suppressing the occurrence of a leakage current due to the high-integration of a semiconductor memory device, thus allowing charges to directly tunnel through the tunneling dielectric layer 250 when injecting or removing the charges into/from the floating gate 260A. The application of the direct tunneling mechanism can contribute to improve an operating speed of a semiconductor memory device and reduce an operating voltage.

FIG. 4 is a scanning electron microscope (SEM) micrograph illustrating silicon nanodots and silicon nitride basal body prepared in accordance with an embodiment of the present invention.

Referring to FIG. 4, it can be observed that the plurality of silicon nanodots serving as the floating gate 260A are formed in the silicon nitride basal body 260. The silicon nanodot has a size of approximately 4.6 nm on the average, and a density of approximately 6.0×10¹¹/cm².

In accordance with the present invention, the leakage current due to the high-integration of the semiconductor memory device can be suppressed between a source electrode and a drain electrode, and between a floating gate and the source and drain electrodes, by forming the source and drain electrodes of metal silicide. Therefore, a change in a threshold voltage of a semiconductor memory device can be prevented, thus making it possible to precisely read data.

Furthermore, it is possible to suppress a leakage current of a floating gate caused by the deterioration of a tunneling dielectric layer through forming the floating gate of a plurality of silicon nanodots, thereby significantly reducing a size of the floating gate to improve integration degree. Also, a retention time can be increased by virtue of a strong trap force of the silicon nanodot.

In addition, since a silicon compound basal body for a floating gate serves as a gate dielectric layer, number of process steps can be reduced, thus reducing a manufacturing cost of a semiconductor memory device.

Moreover, a thickness of the tunneling dielectric layer can be reduced by suppressing the occurrence of a leakage current due to the high-integration of a semiconductor memory device, thus allowing charges to directly tunnel through a tunneling dielectric layer when injecting or removing the charges into/from the floating gate. The application of the direct tunneling can contribute to improve an operating speed of a semiconductor memory device and reduce an operating voltage.

While the present invention has been described with respect to the specific embodiments, it will be apparent to those skilled in the art that various changes and modifications may be made without departing from the spirit and scope of the invention as defined in the following claims.

1. A high density semiconductor memory device, comprising:
source and drain electrodes disposed over a substrate, and forming a Schottky junction with a channel region; and
a floating gate disposed over the substrate of the channel region, and configured with a plurality of nanodots.

2-8. (canceled)

9. The high density semiconductor memory device of claim 1, wherein the source and drain electrodes comprise a material selected from the group consisting of platinum (Pt), lead (Pb) and iridium (Ir) when a hole is used as a majority carrier.

10. (canceled)

11. A method for manufacturing a high density semiconductor memory device, the method comprising the steps of:
a) forming a channel region and source and drain electrodes in a substrate, the source and drain electrodes forming a Schottky junction with the channel region;
b) forming a tunneling dielectric layer over the substrate;
c) forming a floating gate over the tunneling dielectric layer, the floating gate comprising a plurality of nanodots;
d) forming a control gate over the floating gate; and
e) etching the control gate, the floating gate and the tunneling dielectric layer to expose the source and drain electrodes.

12-17. (canceled)

18. The method of claim 11, wherein the source and drain electrodes are formed of a material selected from the group consisting of platinum (Pt), lead (Pb) and iridium (Ir) when a hole is used as a majority carrier.

19. (canceled)
